(19) United States
(12) Patent Application Publication
(10) Pub. No.: US 2026/0162940 A1
(43) Pub. Date: Jun. 11, 2026

(54) PLASMA PROCESSING APPARATUS AND PLASMA PROCESSING METHOD

(71) Applicant: Hitachi High-Tech Corporation, Minato-ku, Tokyo (JP)

(72) Inventors: Tetsuo KAWANABE, Tokyo (JP); Makoto SATAKE, Tokyo (JP)

(21) Appl. No.: 18/690,502

(22) PCT Filed: Jul. 27, 2023
(86) PCT No.: PCT/JP2023/027545

§ 371 Date: Mar. 8, 2024

(30) Foreign Application Priority Data
Feb. 16, 2022 (JP) 2022-021882

(51) Int. Cl. H01J 37/32; H10P 72/00

(52) U.S. Cl. CPC H01J 37/32229; H10P 72/0421

(57) ABSTRACT

In an outer peripheral portion of a wafer, a circumferential variation in a microwave electric-field intensity is minimized, and circumferential uniformity of plasma processing is improved. A plasma processing apparatus includes a circular waveguide, a 90° phase difference plate for the microwaves is provided from above the inside of the circular waveguide, a 180° phase difference plate is provided below the 90° phase difference plate, a rotation drive mechanism is further connected to the 180° phase difference plate. a detector configured to detect a variation in an electric-field intensity in a circumferential direction is connected to a lower portion of the 180° phase difference plate, and a control unit configured to adjust a rotation angle of the 180° phase difference plate to minimize deterioration of axial symmetry of the electric-field intensity detected by the detector.

### TECHNICAL FIELD

The present invention relates to a plasma processing apparatus and a plasma processing method for processing a substrate-shaped sample such as a semiconductor wafer disposed in a processing chamber using a plasma formed in the processing chamber in a vacuum container, such as etching.

### BACKGROUND ART

A semiconductor device has progressed towards a miniaturized or complicated structure in order to attain both an improved calculation capability and low power consumption thereof. Complicated manufacturing steps or highly difficult processing is required, and as a result, a manufacturing cost of the semiconductor device increases. In order to reduce the manufacturing cost, it is required to improve mass productivity by increasing the number of high-quality semiconductor devices manufactured from one semiconductor wafer (hereinafter, also referred to as one wafer as a unit). In order to increase the number of semiconductor devices obtained from one wafer, it is necessary to secure excellent process uniformity in a wafer surface. In particular, since a large number of semiconductor devices can be obtained in an outer peripheral portion of the wafer, it is important to secure excellent process uniformity in a circumferential direction for uniform processing in the outer peripheral portion of the wafer.

In manufacturing of semiconductor devices, plasma processing is widely used, such as plasma etching, plasma chemical vapor deposition (CVD), and plasma ashing. In order to generate a plasma, various methods such as inductively coupled plasma (ICP), capacitively coupled plasma (CCP), electron cyclotron Resonance (ECR), and surface wave excitation plasma are known as a method of applying a DC voltage between electrodes or a method of generating a plasma using radio-frequency power.

In a plasma processing apparatus using a microwave, in order to generate a plasma that is uniform around a central axis of a wafer in a circumferential direction, the microwave is often introduced from a central axis of a to-be-processed wafer toward a direction of a to-be-processed surface of the to-be-processed wafer. However, due to a mode in which the microwave propagates inside a waveguide, electric field distribution is not necessarily axisymmetric. For example, in a TE11 mode, which is a fundamental mode of the microwave propagating inside a circular waveguide, electric field distribution of the microwave is non-axisymmetric. In such a case, in order to make the electric field distribution axisymmetric, it is effective to form a circularly polarized wave by rotating a polarization plane.

In a configuration according to PTL 1, a microwave rotation generator (dielectric plate) is provided in a circular waveguide in order to make electric field distribution in the circular waveguide axisymmetric.

PTL 2 discloses a structure in which a plurality of stubs are provided in a circular waveguide and an insertion amount of the stubs is controlled. Axial symmetry of electric field distribution in the circular waveguide can be improved by the insertion amount of the stubs. The axial symmetry of the electric field distribution can be secured by adjusting the insertion amount of the stubs.

### CITATION LIST

### Patent Literature

PTL 1: JP2010-50046A
PTL 2: JP2003-110312A

### Non Patent Literature

NPL 1: Microwave Circuit (coauthored by Kunihiro Suetake and Shuichi Hayashi, Ohmsha. Ltd., 1958)

### SUMMARY OF INVENTION

### Technical Problem

In a plasma processing apparatus that generates a plasma using a radio-frequency electric field such as a microwave, a microwave rotation generator implemented by a dielectric plate or a 90° phase difference plate is disclosed as a method for forming a circularly polarized wave as described in PTL 1 or NPL 1. In this method, when a reflected wave from an outlet of a waveguide is small, it can be expected that axisymmetric electric field distribution is attained. However, when the reflected wave returned from the inside of a processing chamber is great, an electric-field vibration direction of the microwave incident on the microwave rotation generator or the 90° phase difference plate may deviate from a direction assumed during design, and the axial symmetry of the electric field distribution may be lost. For example, in the plasma processing apparatus, depending on conditions used for processing, the microwave may not be fully absorbed by the plasma and may return to the waveguide. In order to secure the axial symmetry of the electric field distribution under various discharge conditions, it is necessary to dynamically control the electric field distribution.

As a dynamic control method, there is a method of using stubs as described in PTL 2. Examples of a problem in the method of changing the insertion amount of the stubs include that a drive mechanism is required according to the number of stubs and that the control method is complicated. In addition, when the stubs or the drive mechanism is provided, there is also a problem that at least the stubs have a length such that a construction protrudes to the outside of the circular waveguide, and a footprint of the apparatus is large.

An object of the invention is to provide a technique for minimizing a circumferential variation of a microwave electric-field intensity in an outer peripheral portion of a wafer and improving circumferential uniformity of plasma processing.

Other problems and novel features will be clarified according to the description of the present specification and the accompanying drawings.

### Solution to Problem

An outline of a typical aspect according to the invention will be briefly described below.

According to one embodiment, in a plasma processing apparatus in which microwaves in a TE11 mode are coaxially introduced into a processing chamber via a circular waveguide, a 90° phase difference plate for the microwaves is provided from above the inside of the circular waveguide, and a 180° phase difference plate is provided below the 90° phase difference plate. A rotation drive mechanism is connected to the 180° phase difference plate. Further, a detector (measurement unit) that detects a variation in an electric-field intensity in the circumferential direction is connected to a lower portion of the 180° phase difference plate, and a control unit that adjusts a rotation angle of the 180° phase difference plate is provided in a manner of minimizing deterioration of axial symmetry of the electric-field intensity detected by the detector.

### Advantageous Effects of Invention

In the outer peripheral portion of the wafer, the circumferential variation in the microwave electric-field intensity is minimized, and the circumferential uniformity of the plasma processing is improved. Accordingly, since the number of high-quality semiconductor devices manufactured from one semiconductor wafer can be increased, mass productivity of the semiconductor devices can be improved.

### BRIEF DESCRIPTION OF DRAWINGS

FIG. 1 is a cross-sectional view of an etching apparatus according to a first embodiment of the invention.

FIG. 2 is a cross-sectional view of a 90° phase difference plate and a circular waveguide.

FIG. 3 is a diagram illustrating an effect of the 90° phase difference plate.

FIG. 4 is a cross-sectional view of a 180° phase difference plate and the circular waveguide.

FIG. 5 is a diagram illustrating an effect of the 180° phase difference plate.

FIG. 6 is a diagram illustrating an effect of the 180° phase difference plate.

FIG. 7 is an enlarged cross-sectional view from an automatic matching device to the circular waveguide.

FIG. 8 is a cross-sectional view of a plasma processing apparatus provided with a circularly polarized wave detector according to a second embodiment of the invention.

FIG. 9 is an enlarged cross-sectional view of the circularly polarized wave detector.

### DESCRIPTION OF EMBODIMENTS

Hereinafter, embodiments of the invention will be described with reference to the drawings. However, in the following description, the same components are denoted by the same reference signs, and the repeated description thereof may be omitted. The drawings may contain schematic illustrations as compared with actual embodiments for further clarity, but these are merely examples and do not limit the interpretation of the invention.

### Embodiment 1

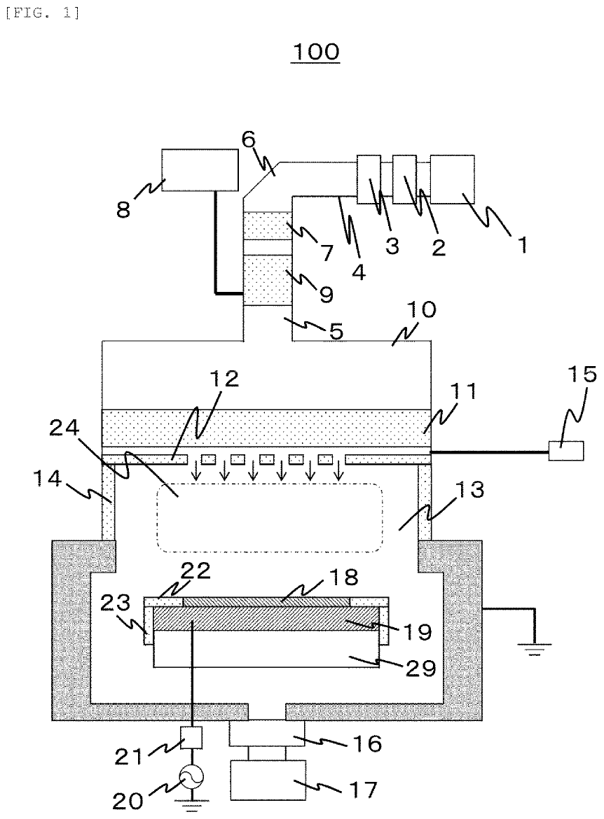

FIG. 1 is a cross-sectional view of an etching apparatus according to a first embodiment of the invention. In a plasma processing apparatus 100 which is the etching apparatus in FIG. 1, a microwave is oscillated from a microwave source 1, and is transmitted from an isolator 2, an automatic matching device 3, and a rectangular waveguide 4 to a circular waveguide 5 via a rounded rectangular converter 6. In the present embodiment, a microwave of 2.45 GHz is used, which is widely used in industries. The isolator 2 is used to protect the microwave source 1 from a reflected wave of the microwave. The automatic matching device 3 is used to adjust a load impedance, prevent the reflected wave, and efficiently supply the microwave. In order to facilitate handling of a phenomenon of microwave propagation, dimensions of a waveguide cross section are defined such that only a microwave in a TE10 mode as a fundamental mode propagates through the rectangular waveguide 4 and only a microwave in a TE11 mode as a fundamental mode propagates through the circular waveguide 5. The circular waveguide 5 is provided with a 90° phase difference plate 7 and a 180° phase difference plate 9 connected to a rotation drive mechanism 8. The microwave introduced into the circular waveguide 5 propagates through the 90° phase difference plate 7, the 180° phase difference plate 9, and a hollow portion 10, and is introduced into a substantially cylindrical plasma processing chamber 13 (also referred to as a processing container) through a microwave introduction window 11 and a shower plate 12. The circular waveguide 5 is provided axisymmetrically with respect to the plasma processing chamber 13.

The hollow portion 10 uses a conductor as a material for reflecting the microwave. For example, aluminum is used as the material of the hollow portion 10.

In order to protect a sidewall of the plasma processing chamber 13 from a plasma, an inner cylinder 14 is provided on an inner side of the sidewall of the plasma processing chamber 13. The inner cylinder 14 located in the vicinity of the plasma uses quartz as a material having high plasma resistance. Alternatively, yttria, alumina, yttrium fluoride, aluminum fluoride, aluminum nitride, or the like may be used as a material having high plasma resistance.

The microwave introduction window 11 and the shower plate 12 use quartz as a material through which the microwave is transmitted. Alternatively, another dielectric material may be used when serving as a material through which the microwave is transmitted. Alternatively, yttria, alumina, yttrium fluoride, aluminum fluoride, aluminum nitride, or the like may be used as a material having high plasma resistance.

Gas is supplied from a gas supply unit 15 between the microwave introduction window 11 and the shower plate 12. The gas supply unit 15 has a function of supplying a desired flow rate by a mass flow controller. In addition, a gas type to be used is appropriately selected according to a to-be-processed film or the like, and a plurality of gas types are supplied in combination at a predetermined flow rate.

A plurality of gas supply holes are formed in the shower plate 12, and gas is supplied to the plasma processing chamber 13 via the gas supply holes. The supplied gas is evacuated to a turbo molecular pump 17 via a conductance adjustment valve 16.

In a lower portion of the plasma processing chamber 13, a combined substrate stage and radio-frequency electrode 19 on which a to-be-processed substrate 18 is placed and an insulating plate 29 below the combined substrate stage and radio-frequency electrode 19 are provided, and bias power is supplied from a bias power supply 20 to the combined substrate stage and radio-frequency electrode 19 via an automatic matching device 21. The to-be-processed substrate 18 is a semiconductor wafer which is a substrate-shaped sample. A central axis of the circular waveguide 5 coincides with a central axis of the plasma processing chamber 13. Further, the central axis of the plasma processing chamber 13 is provided axisymmetrically in a manner of coinciding with a central axis of the combined substrate stage and radio-frequency electrode 19 and coinciding with a central axis of the semiconductor wafer placed on the combined substrate stage and radio-frequency electrode 19.

In order to perform etching as desired, energy of ions incident on the to-be-processed substrate 18 is controlled by adjusting the bias power. The combined substrate stage and radio-frequency electrode 19 is provided with an adsorption mechanism and a temperature adjustment unit (not illustrated) of the to-be-processed substrate 18, and a temperature of the to-be-processed substrate 18 is adjusted as necessary so as to perform the etching as desired.

A susceptor 22 and a stage cover 23 are provided to protect an outer peripheral portion of the combined substrate stage and radio-frequency electrode 19 from the plasma. The susceptor 22 and the stage cover 23 use quartz as a material having high plasma resistance. The etching is performed by generating a plasma 24 in the plasma processing chamber 13 by the microwave supplied from the microwave source 1 and irradiating the to-be-processed substrate 18 with ions or radicals generated in the plasma processing chamber 13.

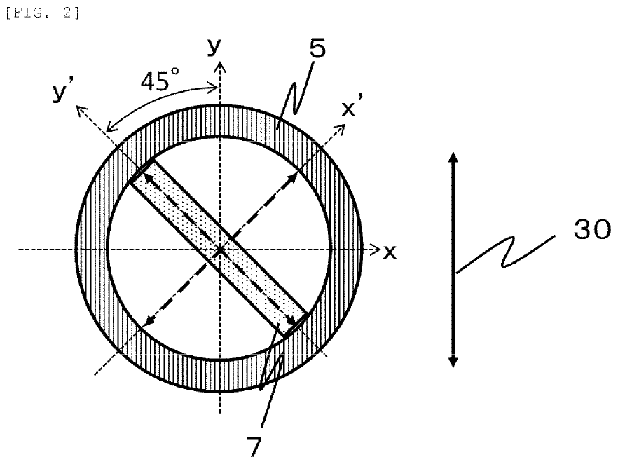

Next, a detailed structure of the inside of the circular waveguide 5 and an effect thereof will be described. First, a detailed structure of the 90° phase difference plate 7 will be described with reference to FIG. 2. FIG. 2 is a top cross-sectional view of the circular waveguide 5 and the 90° phase difference plate 7. A case is considered in which the microwave is introduced with a TE11-mode electric-field vibration direction 30 in a y-axis direction in the drawing and propagates from a front side to a back side of paper. The 90° phase difference plate 7 is provided at an angle rotated by 45° with respect to the electric-field vibration direction. Here, a y′ axis is defined as an axis in a direction of the 90° phase difference plate 7, and an x′ axis is defined as an axis in a direction perpendicular to the γ′ axis. The 90° phase difference plate 7 uses quartz as a dielectric material through which the microwave is transmitted.

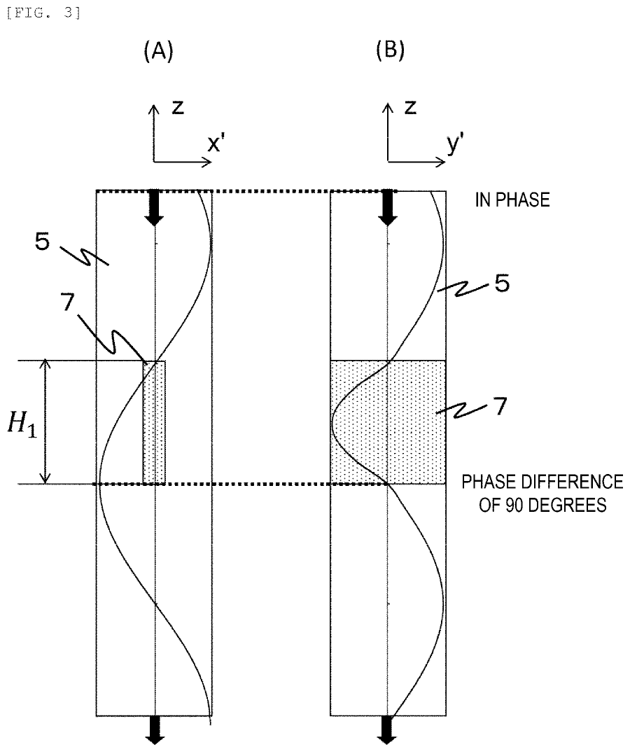

FIG. 3 is a diagram illustrating an effect of the 90° phase difference plate 7. (A) of FIG. 3 is a cross-sectional view of the circular waveguide 5 along an x′-z plane, and (B) of FIG. 3 is a cross-sectional view of the circular waveguide along a y′-z plane. In (A) and (B) of FIG. 3, a curved line in the circular waveguide 5 indicates a wave, (A) of FIG. 3 illustrates a wave having an amplitude in an x′ direction, and (B) of FIG. 3 illustrates a wave having an amplitude in a y′ direction. The microwave having an amplitude in the y-axis direction can be embodied as superposition of waves introduced with the same amplitude while in phase in the x′ direction and the y′ direction. When the microwave passes through the 90° phase difference plate 7, a phase difference between the wave having the amplitude in the x′ direction and the wave having the amplitude in the γ′ direction is 90°. This is because a phase is delayed by 90° when a phase of the wave having the amplitude in the γ′ direction passes through the 90° phase difference plate 7.

As a result, it means that a circularly polarized wave is formed. A height H₁ of the 90° phase difference plate 7 needs to be set to an appropriate value such that a phase difference between a wave having an x′ component and a wave having a y′ component is 90°.

The height H₁ of the 90° phase difference plate 7 is expressed by the following Formula (1).

$${H}_{1} = λ g / ( 4 ( √ {ε}_{r} - 1 ) ) \qquad ( 1 )$$

Here, λg represents a guide wavelength of a microwave in the circular waveguide in a vacuum, and Er represents a dielectric constant of the 90° phase difference plate 7. For example, a guide wavelength of a microwave having a frequency of 2.45 GHz is 203 mm. When a dielectric constant of quartz is 3.8, H₁ is 53.5 mm.

In conclusion, when there is no reflection from the plasma, the circularly polarized wave can be formed using the 90° phase difference plate 7, and the microwave can be uniformly introduced in a circumferential direction. In the present embodiment, a rectangular parallelepiped phase difference plate is illustrated as the 90° phase difference plate 7, but the rectangular parallelepiped shape may not be necessary as long as the 90° phase difference is formed. Since the 90° phase difference plate 7 partially reflects the microwave on an end surface thereof, an angle for forming the 90° phase difference may deviate from 45°. That is, the angle at which the 90° phase difference plate 7 is provided is not necessarily limited to 45° with respect to the electric-field vibration direction, and is appropriately set to an optimum angle according to a reflection coefficient of the microwave of the 90° phase difference plate 7.

As in the present embodiment, when the 90° phase difference plate 7 is provided 45° counterclockwise with respect to the electric-field vibration direction (see FIG. 2), a counterclockwise circularly polarized wave is formed.

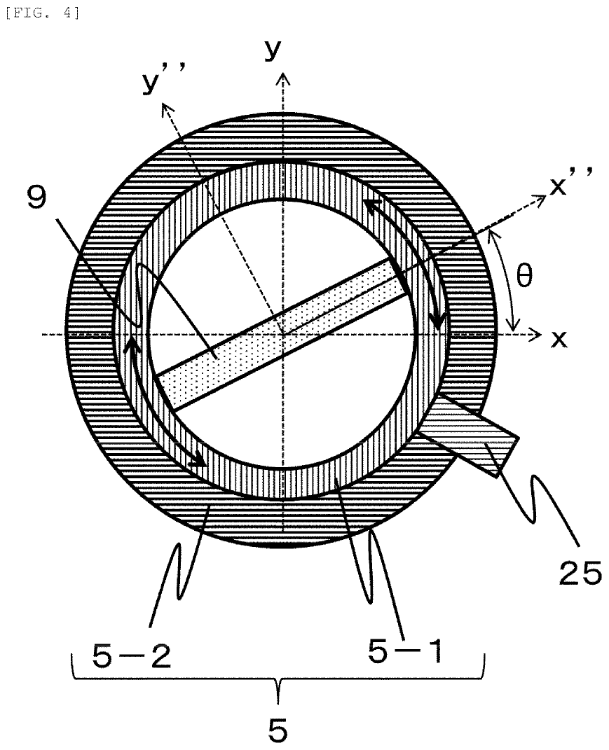

Next, a detailed structure of the 180° phase difference plate 9 connected to the rotation drive mechanism 8 will be described with reference to FIG. 4. FIG. 4 is a top cross-sectional view of the circular waveguide 5 on the periphery of the 180° phase difference plate 9. The circular waveguide 5 has a double structure (5-1, 5-2), and includes an inner-side waveguide 5-1 and an outer-side waveguide 5-2 covering an outer peripheral portion of the inner-side waveguide 5-1. The inner-side waveguide 5-1 supports the 180° phase difference plate 9, and can be integrally rotated with the 180° phase difference plate 9 in a θ direction by an actuator 25 of the rotation drive mechanism 8. The rotation angle of the 180° phase difference plate 9 is monitored by an encoder (not illustrated) at any time. As a material of the 180° phase difference plate 9, for example, quartz is used as the material through which the microwave is transmitted.

For example, the actuator 25 of the rotation drive mechanism 8 is an electromagnetic motor, and a portion connected to the inner-side waveguide 5-1 is a gear or a belt. Alternatively, the actuator 25 may be an ultrasonic motor.

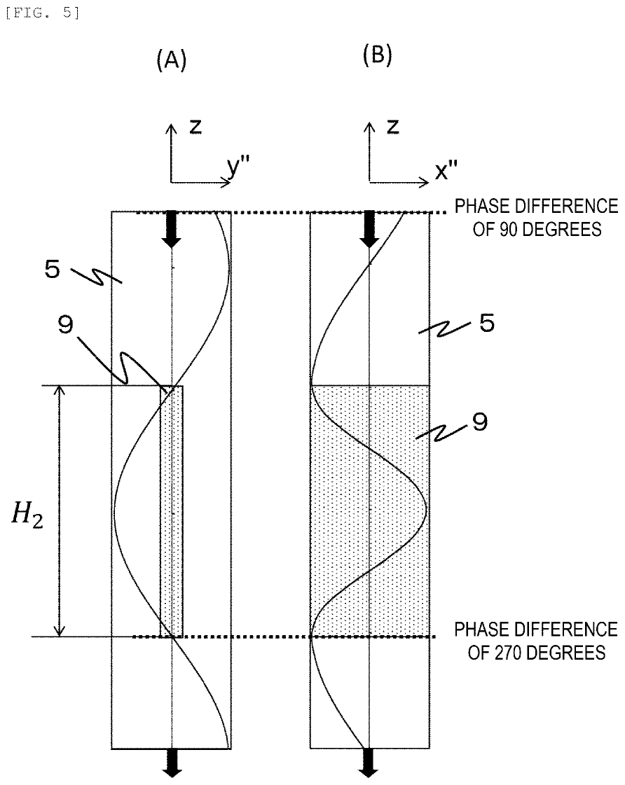

As illustrated in FIG. 4, the 180° phase difference plate 9 is inserted at an angle of θ with respect to an x axis. Here, an axis in the θ direction is defined as an x″ axis, and an axis perpendicular to the x″ axis is defined as a y″ axis. With reference to FIG. 5, an effect when a counterclockwise circularly polarized wave generated by the 90° phase difference plate 7 is incident on the 180° phase difference plate 9 will be described.

(A) of FIG. 5 is a cross-sectional view of the circular waveguide 5 along a y″-z plane, and (B) of FIG. 5 is a cross-sectional view of the circular waveguide 5 along an x″-z plane. A microwave having an amplitude on the x″ axis is delayed by a 180° phase, and as a result, a 180° phase difference is generated between a wave having an x″ component and a wave having a y″ component at an outlet of the 180° phase difference plate 9. Since an incident wave on the 180° phase difference plate 9 is a circularly polarized wave having a 90° phase difference, as a result, a phase difference between the waves having electric-field components on the x″ axis and the y″ axis is 90°+180°=270°. In other words, this means that the incident wave is converted into a clockwise circularly polarized wave.

A height H₂ of the 180° phase difference plate 9 needs to be set to an appropriate value such that a phase difference between the wave having the x″ component and the wave having the y″ component is 180°. The height H₂ of the 180° phase difference plate 9 is expressed by the following Formula (2).

$${H}_{2} = λ g / ( 2 ( √ {ε}_{r} - 1 ) ) \qquad ( 2 )$$

The 180° phase difference plate 9 has an effect of reversing a polarization direction of the circularly polarized wave.

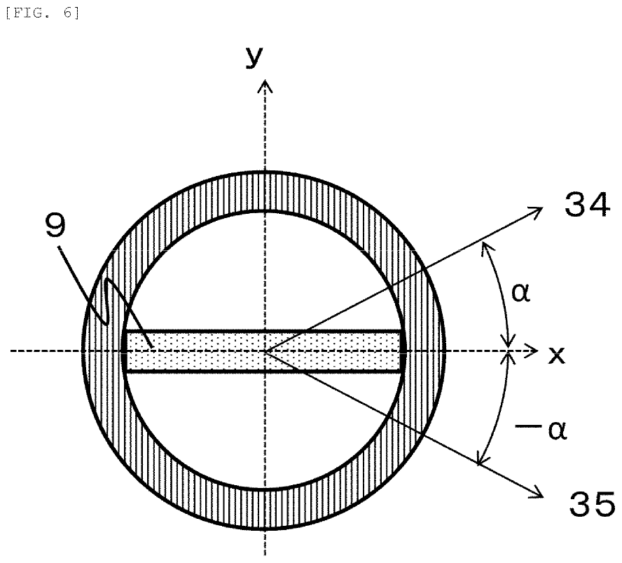

Further, a fact that the 180° phase difference plate 9 has an effect of rotating a polarization plane of a linearly polarized wave will be described with reference to FIG. 6. As illustrated in FIG. 6, a case is considered in which, with an insertion direction of the 180° phase difference plate 9 as an X axis, a linearly polarized wave having an electric-field vibration direction 34 in a direction at an angle α with respect to the x axis is incident on the 180° phase difference plate 9. At this time, a phase of a wave having a component in an x-axis direction is delayed by the 180° phase difference plate 9, so that the microwave passing through the 180° phase difference plate 9 is converted into a linearly polarized wave having an electric-field vibration direction 35 in a direction at an angle −α with respect to the x axis. That is, it means that an angle of the polarization plane of the linearly polarized wave can be adjusted when the rotation angle of the 180° phase difference plate 9 is adjusted.

In conclusion, the 180° phase difference plate 9 has an effect of reversing a rotation direction of the incident circularly polarized wave. The 180° phase difference plate 9 has an effect of causing the polarization plane of the incident linearly polarized wave to rotate. When there is no reflected wave from an outlet of the circular waveguide 5, the linearly polarized wave that is incident on the 90° phase difference plate 7 is converted into a counterclockwise circularly polarized wave, and is converted into a clockwise circularly polarized wave by the 180° phase difference plate 9.

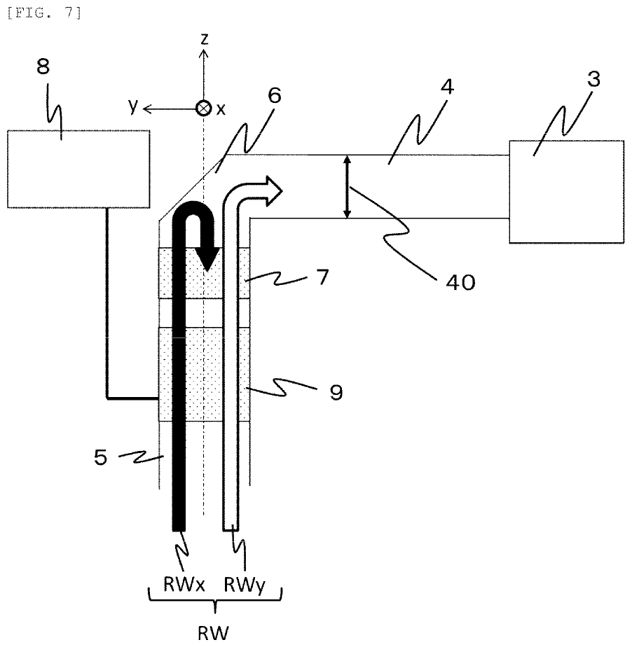

Next, a case in which there is a reflected wave from the outlet of the circular waveguide 5 will be described with reference to FIG. 7. FIG. 7 is an enlarged cross-sectional view from the automatic matching device 3 to the outlet of the circular waveguide 5. When there is a reflected wave, it is assumed that, for example, the microwave supplied to the plasma processing chamber 13 may be reflected without being absorbed by the plasma 24 or may be reflected by a wall surface of the plasma processing chamber 13. A reflected wave RW (RWx: an x-axis component of the reflected wave RW, RWy: a y-axis component of the reflected wave RW) propagates through the circular waveguide 5, the 180° phase difference plate 9, the 90° phase difference plate 7, the rounded rectangular converter 6, and a path opposite to the incident wave. A microwave electric field in the circular waveguide 5 can be embodied by superposition of waves in the TE11 mode having electric-field vibration directions on two independent axes (x axis and y axis in FIG. 7). On the other hand, the rectangular waveguide 4 has an electric-field vibration direction in a uniaxial direction (z axis in FIG. 7) corresponding to the TE10 mode. That is, one degree of freedom in the electric-field vibration direction is lost in a process in which the wave propagating in the circular waveguide 5 is transmitted to the rectangular waveguide 4. Since the TE11 mode having the electric-field vibration direction in the y-axis direction corresponds to a TE10-mode electric-field vibration direction 40 of the rectangular waveguide 4, the wave can propagate toward the automatic matching device 3. On the other hand, in the circular waveguide 5, an electromagnetic wave in the TE11 mode having the electric-field vibration direction in the x-axis direction cannot propagate through a rectangular portion of the rounded rectangular converter 6 and is reflected, and is re-incident on the 90° phase difference plate 7. That is, the microwave incident on the 90° phase difference plate 7 is obtained by adding the wave in the TE11 mode having the electric-field vibration direction in the y-axis direction and the reflected wave RW (RWx) generated by the rounded rectangular converter 6. As a result, when the reflected wave RW enters from the outlet of the circular waveguide 5, axial symmetry of the circularly polarized wave is lost in the 90° phase difference plate 7.

As described above, since the rotation angle of the 180° phase difference plate 9 can be used to adjust the angle of the polarization plane of the linearly polarized wave, an angle of a polarization plane of the microwave re-reflected on the rounded rectangular converter 6 can be adjusted. That is, the polarization plane of the wave incident on the 90° phase difference plate 7 is controlled, and as a result, a circumferential variation in the electric field can be minimized. For example, when the 180° phase difference plate 9 is rotated during plasma processing, it is possible to minimize the circumferential variation in a time-averaged electric field. Alternatively, the circumferential variation in the electric field can be reduced by adjusting the 180° phase difference plate 9 to an optimum angle according to a processing condition used for the plasma processing.

In order to control the 180° phase difference plate 9 to the optimum angle, it is necessary to measure the circumferential variation in the electric field. As an indirect measurement method, for example, a reflection coefficient of a load and a phase thereof may be monitored in the automatic matching device 3 of the microwave, a reflection coefficient at the outlet of the circular waveguide 5 may be estimated, and the rotation angle of the 180° phase difference plate 9 may be adjusted according to the reflection coefficient. As a direct measurement method, an electric-field measurement unit may be provided in the circular waveguide 5.

According to the plasma processing apparatus or a plasma processing method in Embodiment 1, it is possible to minimize the circumferential variation in a microwave electric-field intensity in an outer peripheral portion of the wafer and to improve circumferential uniformity of the plasma processing. Accordingly, since the number of high-quality semiconductor devices manufactured from one semiconductor wafer can be increased, mass productivity of the semiconductor devices can be improved.

### Embodiment 2

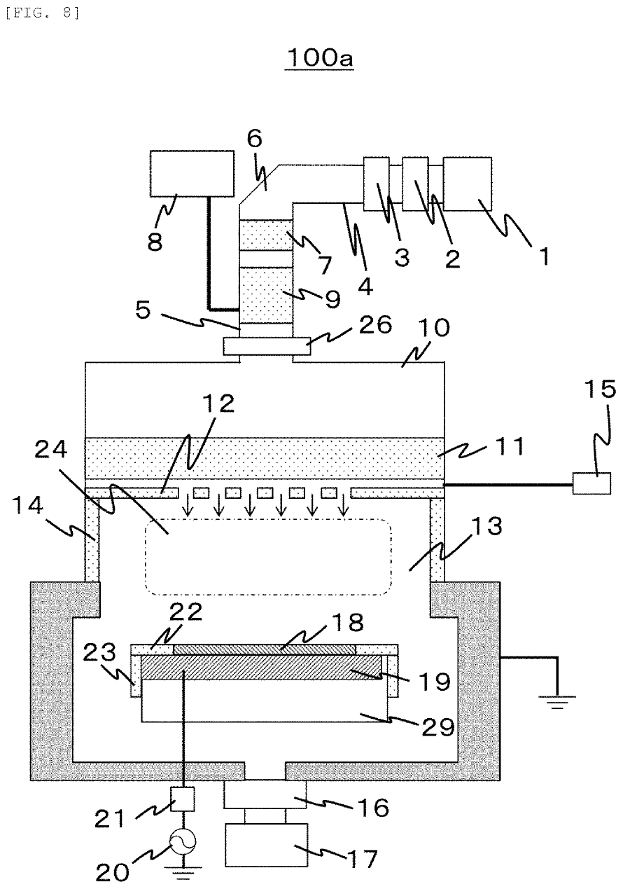

FIG. 8 illustrates a cross-sectional view of a plasma processing apparatus (etching apparatus) according to a second embodiment of the invention. FIG. 8 is a cross-sectional view of a plasma processing apparatus 100a provided with a circularly polarized wave detector 26. As illustrated in FIG. 8, the circularly polarized wave detector 26 is provided downstream (an outlet side of the circular waveguide 5) of the 180° phase difference plate 9. By monitoring a state of the circularly polarized wave by the circularly polarized wave detector 26, an optimum angle of the 180° phase difference plate 9 can be controlled. The circularly polarized wave detector 26 can be regarded as a measurement unit that measures a circumferential electric field in the circular waveguide 5.

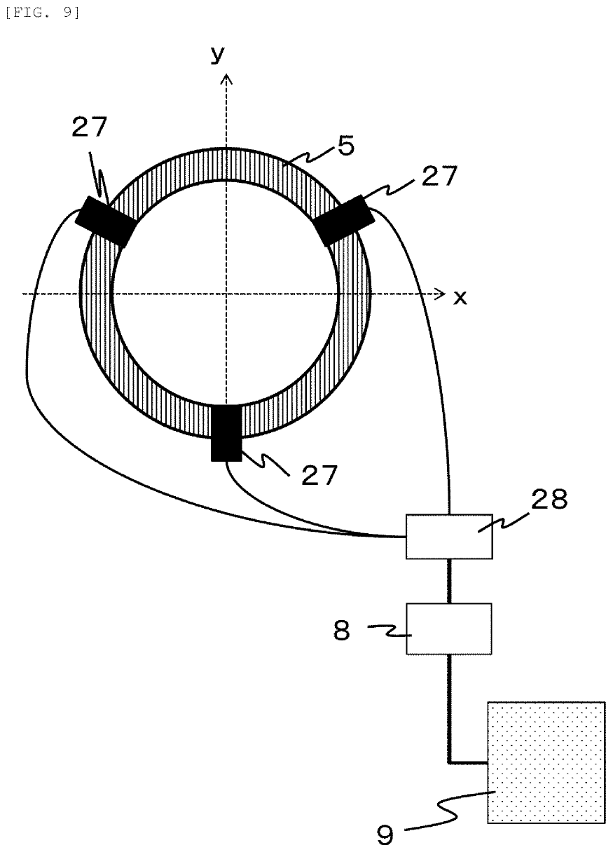

A specific example of the circularly polarized wave detector 26 will be described with reference to FIG. 9. In order to form the circularly polarized wave detector 26, electric-field probes 27 provided at a plurality of are positions of the circular waveguide 5, and a circumferential variation in the electric field is monitored by relatively comparing electric fields determined and measured by the plurality of electric-field probes 27. As the electric-field probe 27, for example, an ore detector is used. At least three or more electric-field probes 27 are provided on a circumference of the circular waveguide 5. In order to detect the circularly polarized wave, it is necessary to prevent positions of electric-field probes 27 from being line-symmetrical positions. A measurement value of each electric-field probe 27 is input to a controller (also referred to as a control unit) 28 to perform arithmetic processing. Based on the arithmetic processing, the controller 28 transmits a control signal for controlling a rotation angle of the 180° phase difference plate 9 to the rotation drive mechanism 8. Accordingly, the controller 28 controls the rotation angle of the 180° phase difference plate 9 and minimizes the circumferential variation in the electric field. In a plasma processing method using the plasma processing apparatus illustrated in FIGS. 8 and 9, the angle of the 180° phase difference plate 9 is adjusted by the controller 28 in a manner of minimizing the circumferential variation in the electric field measured by the circularly polarized wave detector 26 (or the electric-field probe 27) which is the measurement unit.

The plasma processing apparatus or the plasma processing method according to Embodiment 2 can attain the same effect as in Embodiment 1.

Although the invention made by the present inventor has been specifically described above based on the embodiments, it is needless to say that the invention is not limited to the above-described embodiments and examples, and various modifications can be made.

### INDUSTRIAL APPLICABILITY

The invention is applicable to a plasma processing apparatus that processes a sample on a substrate such as a semiconductor wafer by etching or the like.

### REFERENCE SIGNS LIST

1: microwave source
2: isolator
3: automatic matching device
4: rectangular waveguide
5: circular waveguide
5-1: inner-side waveguide
5-2: outer-side waveguide
6: rounded rectangular converter
7: 90° phase difference plate
8: rotation drive mechanism
9: 180° phase difference plate
10: hollow portion
11: microwave introduction window
12: shower plate
13: plasma processing chamber
14: inner cylinder
15: gas supply unit
16: conductance adjustment valve
17: turbo molecular pump
18: to-be-processed substrate
19: combined substrate stage and radio-frequency electrode
20: bias power supply
21: automatic matching device
22: susceptor
23: stage cover
24: plasma
25: actuator
26: circularly polarized wave detector
27: electric-field probe
28: controller
29: insulating plate
30: TE11-mode electric-field vibration direction
34: electric-field vibration direction of microwave incident on 180° phase difference plate
35: electric-field vibration direction of microwave passing through 180° phase difference plate
40: TE10-mode electric-field vibration direction
100, 100a: plasma processing apparatus (etching apparatus)

1. A plasma processing apparatus comprising:
a processing container having a substantially cylindrical shape to which a RF power of microwave is supplied through a matching device;
a rectangular waveguide; and
a circular waveguide; and
a 90° phase difference plate and a 180° phase difference plate each disposed in the circular waveguide.

2. The plasma processing apparatus according to claim 1, further comprising:
a rotation drive mechanism connected to the 180° phase difference plate.

3. The plasma processing apparatus according to claim 1, further comprising:
a measurement unit located below the 180° phase difference plate and configured to measure an electric field in a circumferential direction in the circular waveguide.

4. The plasma processing apparatus according to claim 3, further comprising:
a control unit configured to adjust an angle of the 180° phase difference plate in a manner of minimizing a circumferential variation of the electric field measured by the measurement unit.

5. A plasma processing method using the plasma processing apparatus according to claim 3, the plasma processing method comprising:
adjusting an angle of the 180° phase difference plate in a manner of minimizing a circumferential variation of the electric field measured by the measurement unit.

6. The plasma processing apparatus according to claim 2, further comprising:
a measurement unit located below the 180° phase difference plate and configured to measure an electric field in a circumferential direction in the circular waveguide.

7. The plasma processing apparatus according to claim 6, further comprising:
a control unit configured to adjust an angle of the 180° phase difference plate in a manner of minimizing a circumferential variation of the electric field measured by the measurement unit.

8. A plasma processing method using the plasma processing apparatus according to claim 6, the plasma processing method comprising:
adjusting an angle of the 180° phase difference plate in a manner of minimizing a circumferential variation of the electric field measured by the measurement unit.
